(19) United States
(12) Patent Application Publication
(10) Pub. No.: US 2017/0006707 A1
(43) Pub. Date: Jan. 5, 2017

(54) ELECTRONIC DEVICE MODULE AND METHOD OF MANUFACTURING THE SAME

(71) Applicant: Samsung Electro-Mechanics Co., Ltd., Suwon-si (KR)

(72) Inventors: No Il PARK, Suwon-si (KR); Tae Sung JEONG, Suwon-si (KR); Seung Wook PARK, Suwon-si (KR)

(73) Assignee: Samsung Electro-Mechanics Co., Ltd., Suwon-si (KR)

(21) Appl. No.: 15/058,655

(22) Filed: Mar. 2, 2016

(30) Foreign Application Priority Data
Jun. 30, 2015 (KR) 10-2015-0092651

(51) Int. Cl. H05K 1/18; H05K 3/00; H05K 3/46; H05K 1/02; H05K 3/30

(52) U.S. Cl. CPC H05K 1/185; H05K 1/0298; H05K 1/0218; H05K 3/30; H05K 3/46; H05K 3/0044

(57) ABSTRACT

An electronic device module and method thereof include a first device, a rewiring part, and second devices. The first device is mounted on a surface of a board. The rewiring part is formed along the surface of the board and a contour of the first device. The second devices are mounted on the rewiring part.

### CROSS-REFERENCE TO RELATED APPLICATION

This application claims the priority and benefit under 35 USC 119(a) of Korean Patent Application No. 10-2015-0092651 filed on Jun. 30, 2015, with the Korean Intellectual Property Office, the entire disclosure of which is incorporated herein by reference.

### BACKGROUND

1. Field

The following description relates to an electronic device module having a compact package size, and a method of manufacturing the same.

2. Description of Related Art

To realize miniaturization and lightness of electronic devices, a system on chip (SOC) technology that implements a plurality of individual devices on one chip, a system in package (SIP) technology that integrates a plurality of individual devices in one package, or other similar technology, as well as technology to decrease individual sizes of components mounted in the electronic devices are needed.

In addition, to manufacture an electronic device module having a compact size and high performance, a structure in which electronic components are mounted on both surfaces of a board of the electronic device and a structure in which external terminals are formed on both surfaces of a package have been developed.

However, in a case in which the electronic components are mounted on both surfaces of the board, an entire size of the electronic device module is increased. Thus, an electronic device module is needed in which, although electronic components may be installed or mounted on both surfaces of the board, a compact size of the electronic device is maintained.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In accordance with an embodiment, there is provided an electronic device module, including: a first device mounted on a surface of a board; a rewiring part formed along the surface of the board and a contour of the first device; and second devices mounted on the rewiring part.

The rewiring part may include: an insulating layer attached along one surface of the board and a surface of the first device; and a pattern layer formed on the insulating layer.

The insulating layer may be a photosensitive insulating film.

The electronic device module may also include an underfill layer configured to connect a surface of the first device to the surface of the board.

The second devices may be disposed on at least one of the rewiring part formed on the surface of the board, the rewiring part formed on an upper surface of the first device, and the rewiring part formed on the underfill layer.

An upper end portion of the underfill layer may be disposed on a same plane as the upper surface of the first device or closely positioned to the upper surface of the first device.

The electronic device module may also include a mold part configured to seal the second devices.

At least one of the second devices mounted on the rewiring part formed on one surface of the board may include a thickness greater than a thickness of the first device and thinner than a thickness of the mold part.

The electronic device module may also include a sealing layer sealing the first device, wherein the rewiring layer may be disposed along the surface of the board and a surface of the sealing layer.

The electronic device module may also include a mold part sealing the second devices, wherein the mold part and the sealing layer are formed of the same material.

In accordance with an embodiment, there is provided a method of manufacturing an electronic device module, including: mounting a first device on a surface of a board; forming a rewiring part along the surface of the board and a contour of the first device; and mounting second devices on the rewiring part.

The method may also include: prior to the forming of the rewiring part, forming an underfill layer using an underfill resin to connect the surface of the board to an upper surface of the first device.

The method may also include: prior to the forming of the rewiring part, forming a sealing layer sealing the first device through injection-molding.

The forming of the rewiring part may include: attaching an insulating layer along the surface of the board and the contour of the first device; and forming a conductive pattern layer on the insulating layer.

The method may also include: after the mounting of the second devices, forming a mold part sealing the second devices.

The mounting of the second devices may include mounting a second device having a thickness greater than a thickness of the first device and thinner than a thickness of the mold part on the rewiring part formed on the surface of the board.

The method may also include: performing a primary cutting to expose an inner surface of the board to an exterior of the board; and forming a shield part on an entire outer surface of the mold part and the inner surface of the board.

In accordance with an embodiment, there is provided an electronic device module, including a first device mounted on a portion of a surface of a board; an underfill layer filled in a gap between the first device and the board and along side surfaces of a body of the first device, wherein an upper end portion of the underfill layer is disposed at one of a same plane as an upper surface of the first device and a close proximity to the upper surface of the first device; a rewiring part formed along the surface of the board and an upper contour of the first device; and a second device mounted on the rewiring part.

The second device may include devices positioned on at least one of the rewiring part formed on the surface of the board, the rewiring part formed on an upper surface of the first device, and the rewiring part formed on the underfill layer.

The electronic device module may also include a mold part configured to seal the second device.

Other features and aspects will be apparent from the following detailed description, the drawings, and the claims.

### BRIEF DESCRIPTION OF DRAWINGS

These and/or other aspects will become apparent and more readily appreciated from the following description of the embodiments, taken in conjunction with the accompanying drawings in which:

FIG. 1 is a cross-sectional view schematically illustrating an electronic device module, according to an embodiment;

FIG. 2 is a partially cut-away perspective view illustrating an inner portion of the electronic device module illustrated in FIG. 1;

FIG. 3 is a partially enlarged cross-sectional view of part A of FIG. 1;

FIGS. 4 through 11 are cross-sectional views describing a method of manufacturing the electronic device module illustrated in FIG. 1;

FIG. 12 is a cross-sectional view schematically illustrating an electronic device module, according to another embodiment;

FIG. 13 is a cross-sectional view schematically illustrating an electronic device module, according to another embodiment; and

FIG. 14 illustrates a method to manufacture the electronic device module, in accordance with an embodiment.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

Identical or corresponding elements will be given the same reference numerals, regardless of the figure number, and any redundant description of the identical or corresponding elements will not be repeated. Throughout the description of the present disclosure, when describing a certain relevant conventional technology is determined to evade the point of the present disclosure, the pertinent detailed description will be omitted. Terms such as “first” and “second” can be used in describing various elements, but the above elements shall not be restricted to the above terms. The above terms are used only to distinguish one element from the other. In the accompanying drawings, some elements may be exaggerated, omitted or briefly illustrated, and the dimensions of the elements do not necessarily reflect the actual dimensions of these elements

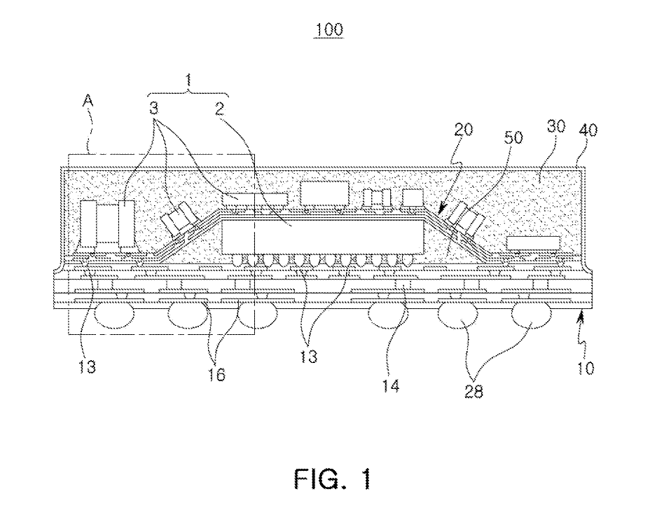

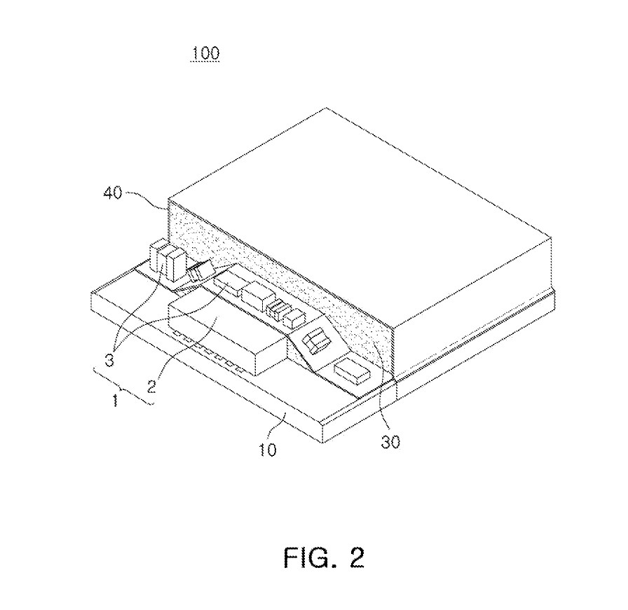

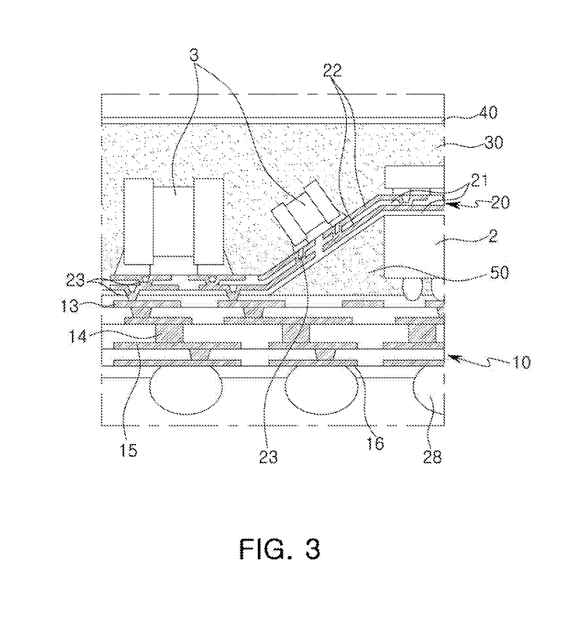

FIG. 1 is a cross-sectional view schematically illustrating an electronic device module according to an exemplary embodiment. In addition, FIG. 2 is a partially cut-away perspective view illustrating an inner portion of the electronic device module illustrated in FIG. 1. FIG. 3 is a partially enlarged cross-sectional view of part A of FIG. 1.

Referring to FIGS. 1 through 3, an electronic device module 100, according to an embodiment includes electronic devices 1, a board 10, a rewiring part 20, and a mold part 30.

The electronic devices 1 includes a first device 2 and second devices 3. A person skill in the art will appreciate that more than one first device 2 may be included and only one second device 3 may be included in the electronic device

The electronic devices 1 are electronic components that may be mounted on the board 10. For example, the electronic devices 1 may be active devices or passive devices. The active devices include, but are not limited to, vacuum tubes, transistors, silicon-controlled rectifiers (SCRs), and TRIACs. The passive devices include, but are not limited to, resistors, capacitors, inductors, transformers, and diodes.

The first device 2 has a large mounting area. For example, the first device 2 has a mounting area occupying half or more of the board 10 and has a flat upper surface. However, the first device 2 is not limited thereto. For instance, the first device 2 may have an uneven upper surface. The first device 2 is mounted on one surface of the board 10. The first device 2 has a flat body, and a plurality of connection terminals are disposed on a lower surface of the body to bond the first device 2 on one surface of the board 10. Therefore, an active device such as an integrated circuit (IC) chip or a package device may be mainly used as the first device 2.

At least one of the second devices 3 is disposed on one surface of the board 10 or is disposed on the first device 2. Therefore, electronic components having a size relatively smaller than that of the first device 2 may be used as at least one of the second devices 3. For example, electronic components having a mounting area relatively smaller than that of the first device 2 may be used as at least one of the second devices 3.

At least one of the second devices 3 having a greater thickness than other devices among the second devices 3 is disposed in the vicinity of the first device 2. In an example, a mounting height of the at least one of the second devices 3 having the greater thickness described above is thicker than a thickness of the first device 2, and is thinner than a thickness of a mold part 30 to be described below.

In addition, at least another of the second devices 3 has a reduced thickness (or a height) among the second devices 3 and is mostly structurally disposed on the first device 2. However, the other second devices 3 having reduced thickness may also be disposed in the vicinity of the first device 2, if necessary.

The electronic devices 1 are mounted on the board 10 in a flip-chip form. However, the electronic devices 1 are not limited thereto, and may also be electrically connected to the board 10 through bonding wires, if necessary.

An underfill layer 50 is provided in a gap between the first device 2 and the board 10. In addition, the underfill layer 50 is formed on side surfaces of the body of the first device 2. In an example, the underfill layer 50 formed on the side surfaces of the body of the first device 2 connects an upper surface of the first device 2 and one surface of the board 10 to each other.

Therefore, an upper end portion of the underfill layer 50 is disposed on the same plane as the upper surface of the first device 2 or is disposed at an approximately similar or close proximity to the upper surface of the first device 2.

In addition, a surface of the underfill layer 50 is formed as an inclined surface connecting the upper surface of the first device 2 and one surface of the board 10 to each other. Although a case in which the inclined surface of the underfill layer 50 is formed as a plane has been illustrated by way of example in FIG. 1, the inclined surface of the underfill layer 50 is not limited thereto. In an alternative embodiment, the underfill layer 50 is formed as a curved surface or as an uneven surface.

The underfill layer 50 is formed of an epoxy resin. In addition, an underfill resin having high viscosity may be selectively used to connect an upper end portion of the underfill layer 50 to the upper surface of the first device 2.

The rewiring part 20 is formed along one surface of the board 10 and the upper surface of the first device 2.

The rewiring part 20 is electrically connected to the board 10 on one surface of the board 10, and electrically connects the second devices 3 disposed on the upper surface of the first device 2 and the board 10 to each other.

Therefore, the rewiring part 20 is formed on the entirety or portions of one surface of the board 10 that is exposed to the exterior of the first device 2 of the board 10. In addition, the rewiring part 20 is formed on the entirety or portions of the upper surface of the first device 2.

The rewiring part 20 includes at least one insulating layer 21 and a pattern layer 22 formed on the insulating layer 21.

The insulating layer 21 is formed of an insulating film, an insulating tape, or other insulating material, having flexibility.

As shown in FIG. 3, at least one connection via 23 is formed in the insulating layer 21. The connection via 23 is bonded to a mounting electrode 13 of the board 10, while penetrating through the insulating layer 21. Therefore, the pattern layer 22 is electrically connected to the board 10 through the connection via 23.

The insulating layer 21 is formed of a photosensitive insulating film. However, the insulating layer 21 is not limited to being formed of the photosensitive insulating film, and may be formed of various insulating materials that include a conductor pattern on one surface thereof.

A bonding member (not illustrated) is interposed between the insulating layer 21 and the board 10 or the first device 2 so that the insulating layer 21 is firmly bonded to the board 10 or the first device 2. The bonding member (not illustrated) is formed of a thin film of which both surfaces have an adhesive property. However, the bonding member is not limited to being formed of the thin film, and may be variously modified. For example, the bonding member may be formed by applying an adhesive material. In addition, in a case in which the adhesive material is applied to the other surface of the insulating layer 21, the bonding member may be omitted.

As shown in FIG. 3, the pattern layer 22 includes a wiring pattern and the connection via 23. The pattern layer 22 electrically connects the second devices 2 to each other or electrically connects the second devices 2 and the board 10 to each other.

In an embodiment, the pattern layer 22 is formed using a process to form a pattern on the board 10. For example, a photolithography process may be used in order to form the pattern layer 22. However, a process of forming the pattern layer 22 is not limited thereto and other processes, such as a patterning processes, may be used to form the pattern layer 22.

The board 10 includes different types of boards such as a ceramic board, a printed circuit board (PCB), a glass board, or a flexible board. In addition, the board 10 may have at least one electronic device 1 mounted on at least one surface thereof.

The board 10 has a plurality of electrodes 13 and 16 formed on both surfaces thereof. In an alternative embodiment, the electrodes 13 and 16 are formed on one surface of the board 10. In an embodiment, the mounting electrodes 13 are configured to mount the electronic devices 1 and the external connecting electrodes 16, to which external terminals 28 are bonded.

The mounting electrodes 13 are electrically connected to the first device 2 or the rewiring part 20. In addition, the external connecting electrodes 16 are electrically connected to external devices through the external terminals 28.

Although not illustrated, the board 10 has a wiring pattern formed on both surfaces thereof in order to electrically connect the mounting electrodes 13 or the external connecting electrodes 16 to each other.

The board 10, according to an embodiment described above, is a multilayer board 10 including a plurality of layers, and a circuit pattern 15 to form an electrical connection is formed between the layers of the multilayer board 10.

In addition, the board 10, according to an embodiment, includes conductive vias 14 electrically connecting the electrodes 13 and 16 and the circuit pattern 15 formed in the board 10 to each other.

The board 10, according to an embodiment described above, is a board in which a plurality of mounting regions are repeatedly disposed or arranged on a lower or an upper surface of the board 10 or in-between layers of the board 10 in order to simultaneously manufacture a plurality of individual modules. For instance, the board 10 is a board having a quadrangular form with a wide area and having a long strip form. In this case, the electronic device module 100 is manufactured for each of a plurality of individual module mounting regions.

The mold part 30 seals the electronic devices 1 mounted on the board 10. In addition, the mold part 30 is provided between the electronic devices 1 mounted on the board 10 to prevent an electrical short-circuit from being generated between the electronic devices 1. The mold part 30 also fixes the electronic devices 1 onto the board 10, while enclosing outer portions of the electronic devices 1, thereby safely protecting the electronic devices 1 from external impact.

In an embodiment, the mold part 30 is formed using an injection-molding or molding method, and is formed of, for example, an epoxy mold compound (EMC). However, the mold part 30 is not limited to being formed by the above-mentioned injection-molding or molding method, and may be formed by various methods such as a method of pressing a resin in a semi-hardened state in order to form the mold part 30.

The mold part 30, according to an embodiment, covers the entirety of one surface of the board 10. A case in which all of the electronic devices 1 are embedded in the mold part 30 has been described by way of example in the present embodiment. However, all of the electronic devices 1 are not limited to being embedded in the mold part 30, and may be variously applied. For example, at least one of the electronic devices 1 embedded in the mold part 30 may be partially exposed to the exterior of the mold part 30.

A shield part 40 accommodates the mold part 30 therein. That is, the shield part 40 closely adheres to the mold part 30 to cover an outer surface of the mold part 30.

The shield part 40 is electrically connected to a ground pattern (not illustrated) of the board 10 in order to shield against electromagnetic waves.

The shield part 40 is formed of various materials having conductivity. For example, the shield part 40 is formed of a resin containing conductive powder or may be formed by directly forming a metal thin film. In a case of forming the metal thin film, various technologies such as a sputtering method, a vapor deposition method, an electroplating method, and an electroless plating method may be used.

In particular, the shield part 40, according to an embodiment is a metal thin film formed by a conformal coating method. In accordance with an embodiment, the conformal coating method is advantageous, at least, in that a uniform coating film is formed and a cost required for equipment investment is small compared to other processes. However, the shield part 40, according to an embodiment is not limited thereto, and other processes to form the shield part 40 may be variously applied.

Next, a method to manufacture an electronic device module 100, according to an embodiment, will be described.

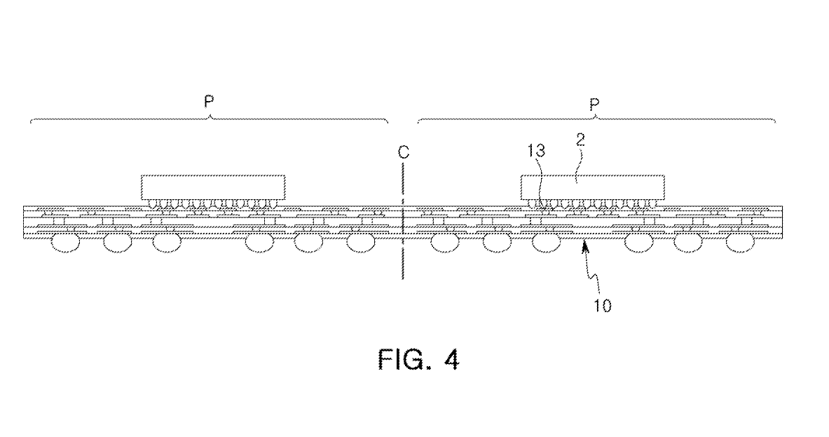

FIGS. 4 through 11 are cross-sectional views to describe a method of manufacturing the electronic device module illustrated in FIG. 1.

Referring to FIGS. 4 through 11, the first device 2 is mounted on one surface, that is, an upper surface, of the board 10, as illustrated in FIG. 4.

As described above, the board 10, according to an embodiment is a multilayer circuit board 10 including a plurality of layers. Patterns electrically connected to each other may be formed between the respective layers. Also, patterns electrically connected to each other may be formed on an upper or a lower portions of the board 10.

In addition, a board (hereinafter referred to as a strip board) having a strip form is used as the board 10, in accord with an embodiment. In accordance with an embodiment, one of the many purposes of the strip board 10 is to simultaneously manufacture a plurality of individual electronic device modules 100, a plurality of individual device module regions P is divided by a cutting line C on the strip board 10, and the electronic device module 100 is manufactured in each of the plurality of individual device module regions P.

The first device 2 is repeatedly mounted in all of the individual device module regions P of the board 10. That is, kinds or types and a number of electronic device modules 100 disposed and mounted in each of the individual device module regions P may be the same.

Furthermore, a case in which only one first device 2 is mounted in one individual device module region P has been described by way of example, in accord with an embodiment. However, the number of first devices 2 mounted in one individual device module region P is not limited to one, and may also be plural, if necessary.

The first device 2 is mounted on the board 10 by printing solder paste on the mounting electrodes 13 formed on one surface of the board 10 by a screen printing method, seating the first device 2 on the solder paste, and then applying heat to the solder paste by a reflow process to melt and harden the solder paste.

However, a method of mounting the first device 2 is not limited thereto, and may vary depending on a shape of the first device 2. For example, after the first device 2 is attached onto one surface of the board 10, the mounting electrodes 13 formed on the board 10 and electrodes of the electronic devices 1 may be electrically connected to each other using bonding wires.

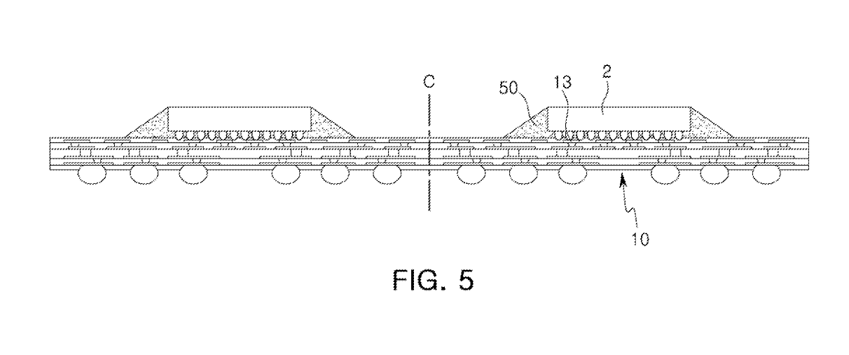

Then, as illustrated in FIG. 5, the underfill layer 50 is formed by injecting an underfill solution between the first device 2 and the board 10. In one configuration, the underfill solution is filled in a gap between the first device 2 and the board 10, and is injected along the side surfaces of the body of the first device 2.

The upper end portion of the underfill layer 50 is disposed on the same plane as the upper surface of the first device 2 or is disposed at an approximately similar or a close proximity to the upper surface of the first device 2. Therefore, the surface of the underfill layer 50 is formed as an inclined surface connecting the upper surface of the first device 2 and one surface of the board 10 to each other.

The underfill layer 50 is formed of an epoxy resin. In addition, an underfill resin having high viscosity is selectively used to connect an upper end portion of the underfill layer 50 to the upper surface of the first device 2. In addition, a plurality of underfill solutions having different viscosities may also be sequentially used, if necessary.

Then, the rewiring part 20 is formed.

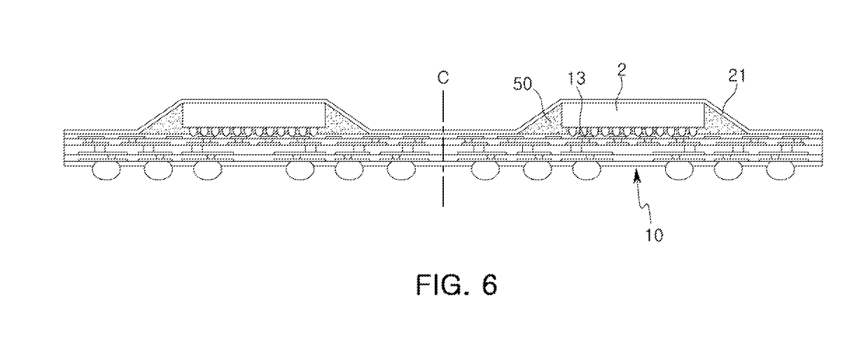

As illustrated in FIG. 6, the insulating layer 21 is formed.

The insulating layer 21 is attached along a surface formed by the board 10, the first device 2, and the underfill layer 50. In an example, the insulating layer 21 is attached onto the entirety of the above-mentioned surface, or is attached onto portions of the above-mentioned surface, if necessary.

The insulating layer 21 is attached onto the above-mentioned surface through a separate adhesive member. However, the insulating layer 21 is not limited to being attached onto the above-mentioned surface through the adhesive member. That is, in a case in which an adhesive material is applied to the insulating layer 21, the adhesive member may be omitted.

The insulating layer 21 is firmly attached onto the above-mentioned surface using a vacuum lamination method. However, a method of attaching the insulating layer 21 is not limited thereto.

In addition, in order to easily form the pattern layer 22 on the insulating layer 21, the insulating layer 21, according to an embodiment, is formed of the photosensitive insulating film. However, other types of insulating films may be used to form the insulating layer 21.

Furthermore, after the insulating layer 21 is formed, surface treatment is performed on the insulating layer 21 in order to increase close adhesion between the pattern layer 22 and the insulating layer 21. The surface treatment may be performed using chemicals, a laser, ultraviolet (UV) light, or the like, but is not limited thereto.

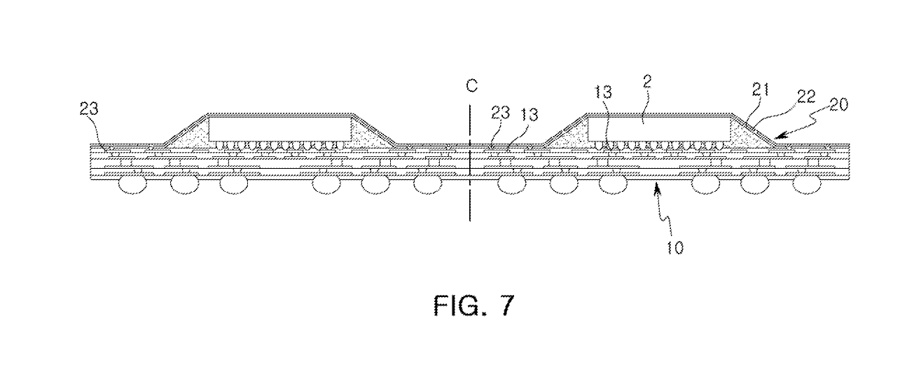

As illustrated in FIG. 7, the pattern layer 22 is formed on the insulating layer 21.

In an example, at least one through-via is first formed in the insulating layer 21. The mounting electrode of the board 10 may be exposed to the outside by the through-via.

Then, the pattern layer 22 is formed. The pattern layer 22 is formed using a general process to form a pattern of the board 10. For example, a photolithography process may be used in order to form the pattern layer 22, but is not limited thereto.

In addition, in accord with an embodiment, a conductive material is filled in the through-via to form the connection via 23. The pattern layer 22 is electrically connected to the mounting electrode of the board 10 by the connection via 23.

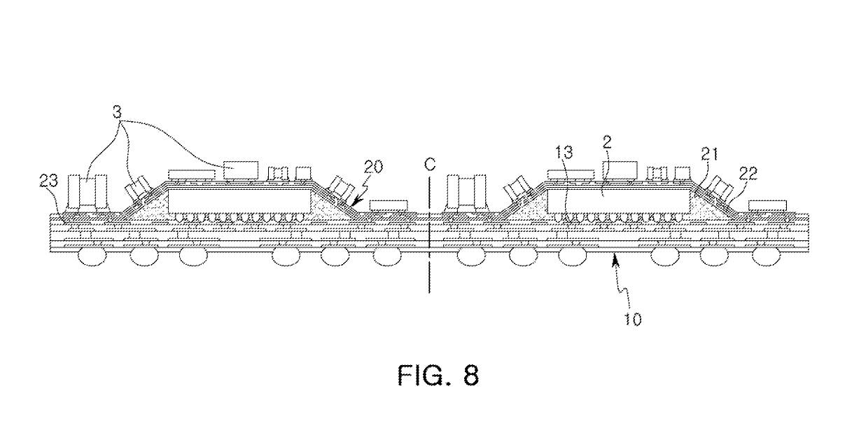

Furthermore, FIG. 7 illustrates the rewiring part 20 in which only one insulating layer 21 and only one pattern layer 22 are formed. However, a configuration of the rewiring part 20 is not limited thereto. That is, the pattern layer 22 is formed as multiple layers, if necessary, as illustrated in FIG. 8. This may be implemented by repeatedly performing processes of FIGS. 6 and 7.

When the rewiring part 20 is completed, the second devices 3 are mounted on the rewiring part 20, as illustrated in FIG. 8.

The second devices 3 are mounted at various positions on the rewiring part 20. For example, at least one of the second devices 3 is mounted on the rewiring part 20 formed on the board 10 or is mounted on the rewiring part 20 formed on the first device 2.

In addition, at least one of the second devices 3, according to an embodiment, is also formed on the rewiring part 20 formed on the underfill layer 50. In this case, the rewiring part 20 is formed as an inclined surface. Therefore, the at least one of the second devices 3 may also be obliquely mounted along the corresponding inclined surface.

Because the second device 3 mounted on the inclined surface is seated on the inclined surface through a conductive adhesive such as a solder paste, light devices, such as a chip device, is used as the second device 3 mounted on the inclined surface.

In addition, a device mounted on the rewiring part 20 formed on the board 10, among the second devices 3, includes a device having increased thickness (or height). In an example, a thickness of the device having the increased thickness, as described above, is thicker than that of the first device 2 and corresponds to or is thinner than that of the mold part 30.

Devices having reduced thickness are mainly disposed on the rewiring part 20 formed on the first device 2.

As described above, the second devices 3 are disposed at various positions depending on sizes or thicknesses thereof.

The second devices 3 are mounted by printing solder paste on the rewiring part 20 using a screen printing method, seating the second devices 3 on the solder paste, and then applying heat to the solder paste by a reflow process to melt and harden the solder paste.

However, a method to mount the second devices 3 is not limited thereto, and may be variously modified. For example, the second devices 3 may be mounted using bonding wires.

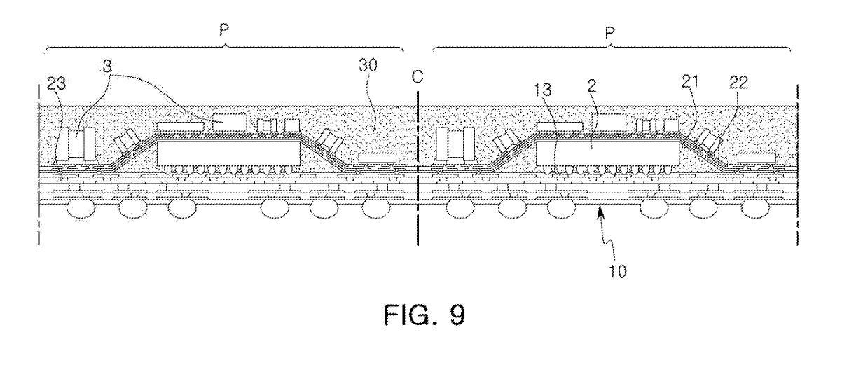

Next, as illustrated in FIG. 9, the mold part 30 is formed on one surface of the board 10.

After the board 10 on which the electronic devices 1 are mounted is disposed in a mold (not illustrated), a molding resin is injected into the mold to form the mold part 30. Therefore, the electronic devices 1 mounted on the board 10 are protected from external factors by the mold part 30.

In accordance with an embodiment, the mold part 30 has an integral shape to cover all of the respective individual device module regions P on the strip board 10. However, the mold part 30 may also be separated for each of the individual device module regions P, if necessary.

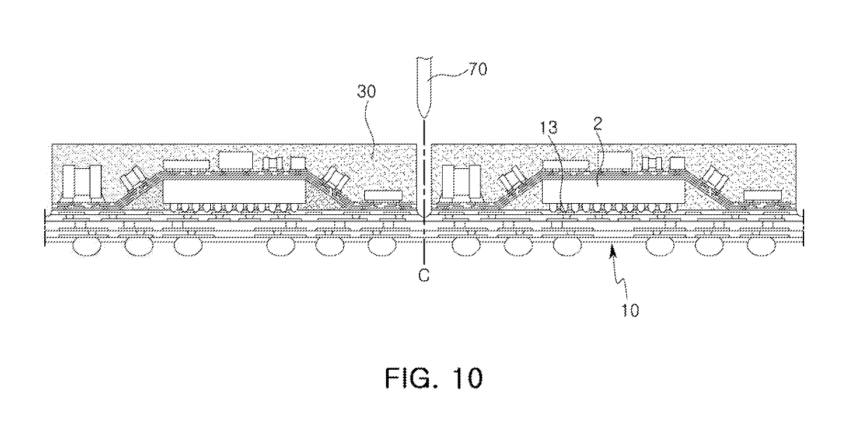

Next, as illustrated in FIG. 10, primary cutting is performed.

The primary cutting is performed using a blade 70. That is, the mold part 20 and a portion of the formed board 10 is cut along a boundary C (or a cutting line) between the individual device module regions P using the blade 70. In this embodiment, a portion of a ground pattern of the board 10 is cut by the blade 70 to expose the ground pattern to the exterior of the board 10.

As described above, in the primary cutting, a half dicing process to conduct cutting up to a portion of the strip board 10 is performed. Therefore, the strip board 10 is not completely cut, and may be maintained in a connected state.

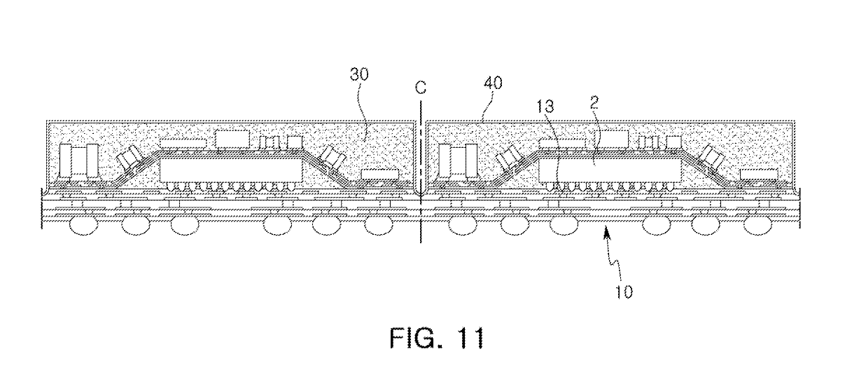

Then, as illustrated in FIG. 11, the shield part 40 is formed. As illustrated in FIG. 11, the shield part 40 is formed on the entirety of an outer surface of the mold part 30 and an inner surface of the board 10 exposed through the primary cutting. Therefore, the shield part 40 is electrically connected to the ground pattern exposed to the outside through the cutting surface of the board 10.

As described above, the shield part 40 is formed by the metal thin film. In this case, the metal thin film is formed by a conformal coating method. The conformal coating method may be used to form a uniform coating film, has a lower equipment investment cost and excellent productivity, and is environmentally-friendly compared to other thin film forming methods, for example, an electroplating method, an electroless plating method, and a sputtering method. However, the metal thin film is not limited to being formed by the conformal coating method, and may be formed by such other thin film forming methods, if necessary.

Furthermore, in the method of manufacturing the electronic device module 100, in accordance with an exemplary embodiment, plasma treatment is performed on the shield part 40 to improve abrasion resistance and corrosion resistance of a surface of the shield part 40, after the shield part 40 is formed.

In addition, secondary cutting is performed to cut the remaining portion of the strip board 10, onto which the shield part 40 is formed, to form the individual electronic device module 100 illustrated in FIG. 1. In the secondary cutting, upper and lower surfaces of the board 10 onto which the shield part 40 is formed are cut at a time using the blade (not illustrated). In an example, the blade approaches the board 10 rather than the mold part 30 to cut the board 10.

As a result, the board 10 having the strip form may be completely separated into the respective individual electronic device modules 100 (see FIG. 1).

In the electronic device module, according to an embodiment manufactured as described above, the second devices 3 are mounted on the first device 2, which is mounted on the board 10. In addition, because the insulating layer 21 having a film form rather than the board 10 is used as the rewiring part 20, an increase in a thickness of the electronic device module is significantly decreased compared to an embodiment in which two boards 10 are used.

Further, the second device 3 are mounted on the inclined surface formed by the underfill layer 50.

Therefore, a large number of electronic devices may be mounted in the electronic device module 100, while significantly decreasing a volume of the electronic device module.

In addition, because the lower surface of the board 10 is exposed to the outside, even though significant heat is generated in the first device 2 mounted on the board 10, the heat is smoothly radiated through the board 10.

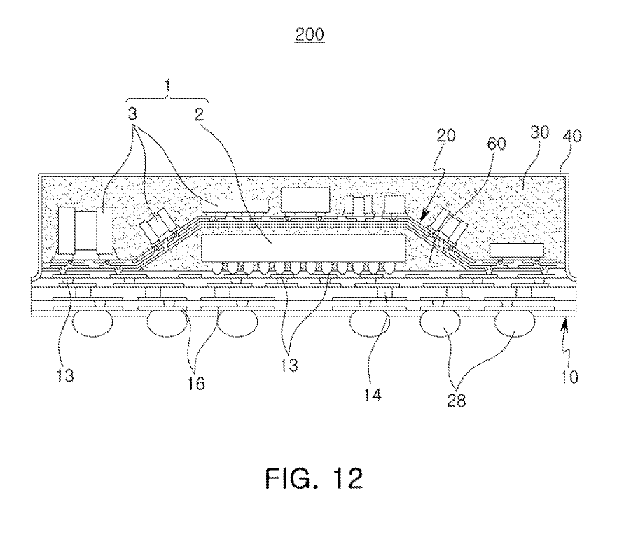

FIG. 12 is a cross-sectional view schematically illustrating an electronic device module, according to another embodiment.

Referring to FIG. 12, an electronic device module 200, according to an embodiment, uses a sealing layer 60 rather than the underfill layer 50 (see FIG. 1).

The sealing layer 60 is formed of the same material as that of the mold part 30, and is formed through injection-molding, similar to the mold part 30. For example, the sealing layer 60 is formed of an epoxy mold compound (EMC).

The sealing layer 60 covers an upper surface of the first device 2. Therefore, the rewiring part 20 is formed along surfaces of the board 10 and the sealing layer 60.

Because the sealing layer 60, according to an embodiment, has a thickness greater than that of the underfill layer 50 described above, the electronic device module 200, according to an embodiment, has a thickness greater than that of the electronic device module 100, according to the exemplary embodiment described above. However, a configuration of the electronic device module 200, according to an embodiment, is not limited thereto. That is, the rewiring part 20 may be formed after the sealing layer 60 is formed so that the upper surface of the first device 2 is exposed, similar to the embodiment described above.

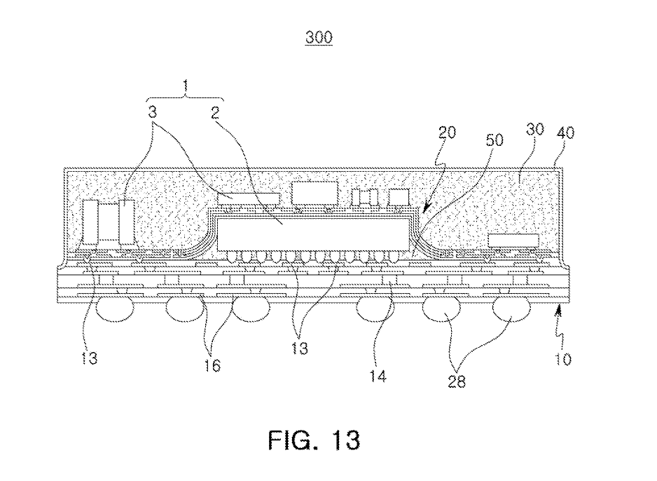

FIG. 13 is a cross-sectional view schematically illustrating an electronic device module, according to another embodiment.

Referring to FIG. 13, an electronic device module 300, according to an embodiment, includes an underfill layer 50. The underfill layer 50 does not connect the upper surface of the first device 2 and the board 10 to each other, and may be provided in a gap between the first device 2 and the board 10.

Therefore, the rewiring part 20 includes regions disposed in an approximately vertical direction along the side surfaces of the first device 2.

In this example, it may be difficult to mount the second devices 3 on the rewiring part 20 formed on the underfill layer 50. However, because the underfill layer 50 is easily implemented, the electronic device module 300 is easily manufactured.

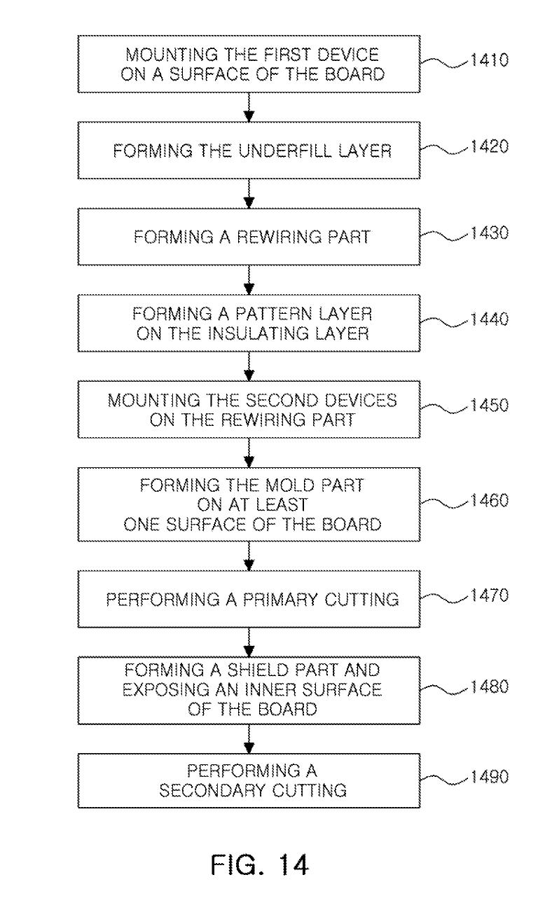

FIG. 14 illustrates a method to manufacture the electronic device module, as previously discussed in FIGS. 4 through 11, in accordance with an embodiment. At operation 1410, the method mounts the first device 2 on a surface of the board 10. In an embodiment, the method repeatedly mounts the first device 2 in all of the individual device module regions P of the board. At operation 1420, the method forms the underfill layer 50 by injecting an underfill solution between the first device 20 and the board 10. At operation 1430, the method forms a rewiring part 20. At operation 1440, the method forms a pattern layer 22 on the insulating layer 21. When the rewiring part 20 is completed, at operation 1450, the method mounts the second devices 3 on the rewiring part 20. At operation 1460, the method forms the mold part 30 on at least one surface of the board 10. At operation 1470, the method performs a primary cutting using the blade 70 and exposes a ground pattern to an exterior of the board 10. At operation 1480, the method forms a shield part 40 on an entire outer surface of the mold part 30 and an inner surface of the board 10 exposed through the primary cutting. At operation 1490, the method performs a secondary cutting to cut the remaining portion of the strip board 10 on which the shield part 40 is formed to form the electronic device module 100.

As set forth above, in the electronic device modules according to various embodiments, the second devices are mounted on the first device mounted on the board. In addition, because the insulating layer having the film form rather than the board is used as the rewiring part, the increase in the thickness of the electronic device module is significantly decreased compared to a case in which two boards are used.

Further, the second device is also formed on the inclined surface formed by the underfill layer or the sealing layer.

Therefore, a large number of electronic devices may be mounted in the electronic device module, while significantly decreasing a volume of the electronic device module.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An electronic device module, comprising:
a first device mounted on a surface of a board;
a rewiring part formed along the surface of the board and a contour of the first device; and
second devices mounted on the rewiring part.

2. The electronic device module of claim 1, wherein the rewiring part comprises:
an insulating layer attached along one surface of the board and a surface of the first device; and
a pattern layer formed on the insulating layer.

3. The electronic device module of claim 2, wherein the insulating layer is a photosensitive insulating film.

4. The electronic device module of claim 1, further comprising:
an underfill layer configured to connect a surface of the first device to the surface of the board.

5. The electronic device module of claim 4, wherein the second devices are disposed on at least one of the rewiring part formed on the surface of the board, the rewiring part formed on an upper surface of the first device, and the rewiring part formed on the underfill layer.

6. The electronic device module of claim 4, wherein an upper end portion of the underfill layer is disposed on a same plane as the upper surface of the first device or closely positioned to the upper surface of the first device.

7. The electronic device module of claim 1, further comprising:
a mold part configured to seal the second devices.

8. The electronic device module of claim 7, wherein at least one of the second devices mounted on the rewiring part formed on one surface of the board comprises a thickness greater than a thickness of the first device and thinner than a thickness of the mold part.

9. The electronic device module of claim 1, further comprising:
a sealing layer sealing the first device,
wherein the rewiring layer is disposed along the surface of the board and a surface of the sealing layer.

10. The electronic device module of claim 8, further comprising:
a mold part sealing the second devices, wherein the mold part and the sealing layer are formed of the same material.

11. A method of manufacturing an electronic device module, comprising:
mounting a first device on a surface of a board;
forming a rewiring part along the surface of the board and a contour of the first device; and
mounting second devices on the rewiring part.

12. The method of claim 11, further comprising:
prior to the forming of the rewiring part, forming an underfill layer using an underfill resin to connect the surface of the board to an upper surface of the first device.

13. The method of claim 11, further comprising:
prior to the forming of the rewiring part, forming a sealing layer sealing the first device through injection-molding.

14. The method of claim 11, wherein the forming of the rewiring part comprises:
attaching an insulating layer along the surface of the board and the contour of the first device; and
forming a conductive pattern layer on the insulating layer.

15. The method of claim 11, further comprising:
after the mounting of the second devices, forming a mold part sealing the second devices.

16. The method of claim 15, wherein the mounting of the second devices comprises mounting a second device having a thickness greater than a thickness of the first device and thinner than a thickness of the mold part on the rewiring part formed on the surface of the board.

17. The method of claim 16, further comprising:
performing a primary cutting to expose an inner surface of the board to an exterior of the board; and
forming a shield part on an entire outer surface of the mold part and the inner surface of the board.

18. An electronic device module, comprising:
a first device mounted on a portion of a surface of a board;
an underfill layer filled in a gap between the first device and the board and along side surfaces of a body of the first device, wherein an upper end portion of the underfill layer is disposed at one of a same plane as an upper surface of the first device and a close proximity to the upper surface of the first device;
a rewiring part formed along the surface of the board and an upper contour of the first device; and
a second device mounted on the rewiring part.

19. The electronic device module of claim 18, wherein the second device comprises devices positioned on at least one of the rewiring part formed on the surface of the board, the rewiring part formed on an upper surface of the first device, and the rewiring part formed on the underfill layer.

20. The electronic device module of claim 1, further comprising:
a mold part configured to seal the second device.
